(19) United States
(12) Patent Application Publication
(10) Pub. No.: US 2011/0115001 A1
(43) Pub. Date: May 19, 2011

(54) ELECTRONIC CONTROL DEVICE

(75) Inventor: Toshihiko FUJII, Kobe-shi (JP)

(73) Assignee: FUJITSU TEN LIMITED, Kobe-shi (JP)

(21) Appl. No.: 12/944,991

(22) Filed: Nov. 12, 2010

(30) Foreign Application Priority Data
Nov. 17, 2009 (JP) 2009-262202

(51) Int. Cl. H01L 29/78

(52) U.S. Cl. 257/288; 257/E29.255

(57) ABSTRACT

An electronic control device controls a control object. An electronic component configured to control the control object is mounted on an electronic substrate. An electrical signal line is formed on the electronic substrate. The electrical signal line transmits an electrical signal. A metal is press-fitted into the electronic substrate and passes through the electronic substrate to be exposed to both surfaces of the electronic substrate. An electronic element has a contact surface portion which comes into contact with a surface of the electronic substrate when the electronic element is mounted on the electronic substrate. The electronic element is connected to the electrical signal line. The electronic element is mounted on the electronic substrate such that the contact surface portion comes into contact with the metal exposed to the both surfaces of the electronic substrate and the electrical signal line connected to the contact surface portion does not come into contact with the metal.

The disclosure of Japanese Patent Application No. 2009-262202 filed on Nov. 17, 2009, including specification, drawings and claims is incorporated herein by reference in its entirety.

### BACKGROUND

The present invention relates to a technique for the structure of an electronic control device.

FIG. 1 shows a MOS field effect transistor, particularly, an electronic element called a power MOSFET. A transistor is used to control, for example, a motor that is a control object. In particular, a power MOSFET can output large current (for example, 45 A) and can perform the PWM control of a motor, which can output large torque, by a switch function thereof.

In the power MOSFET, as shown in FIG. 1, a transistor chip 5, which is an electronic element, is sealed by a package 2. A source electrode and a gate electrode, among three electrodes of the transistor chip 5, are electrically connected to terminals 3 and 4, and these terminals are provided on the outside of the package 2. Further, as shown in FIG. 2 showing the back of the power MOSFET 1, a drain electrode, among the three electrodes of the transistor chip 5, is electrically connected to a terminal plate 6 and is exposed on the bottom of the package. The reason why only the drain electrode is disposed on the bottom of the package as described above is to achieve high integration and large power, and the power MOSFET 1 having this structure is suitable for achieving a reduction of the size of a control substrate and the PWM control of a motor that outputs large torque.

If a voltage is applied between the gate electrode and the drain electrode of the power MOSFET 1 when the PWM control of a motor is performed by the realization of the switch function of the power MOSFET 1, on-resistance is increased, so that heat is generated. For this reason, the terminal plate 6, which is exposed on the bottom of the package 2 of the power MOSFET 1 as shown in FIG. 2, also has a function of radiating heat generated in the package.

FIG. 3 shows an electronic control device 7 where electronic components such as the power MOSFET 1 are mounted on a surface of an electronic substrate 8. If the power MOSFET 1 is mounted on the surface of the electronic substrate 8 as shown in FIG. 3, the surface of the terminal plate 6 comes into contact with the surface of the electronic substrate 8. Accordingly, the heat of the terminal plate 6 is transferred to the electronic substrate 8, so that a predetermined heat radiation effect is obtained. However, since a material of the electronic substrate 8 is a resin which does not have good thermal conductivity, the heat radiation effect of the electronic substrate is limited. If the heat radiation effect of the electronic substrate is not sufficient, there is a concern that this will cause the deterioration or failure of the power MOSFET 1 or the deterioration or failure of peripheral components.

As a technique to further obtain a heat radiation effect, there is a technique for obtaining a heat radiation effect by forming through holes at positions where the terminal plate 6 of the power MOSFET 1 comes into contact with the surface of the electronic substrate 8. In addition, there is a technique to further obtain a heat radiation effect by embedding metal columns in the above-mentioned positions. Specifically, the metal columns pass through the electronic substrate 8 and are exposed to the contact surface of the electronic substrate and the surface of the electronic substrate opposite to the contact surface, and the exposed portions of the metal columns are embedded in the electronic substrate so as to be flush with both surfaces of the electronic substrate 8. Accordingly, metal having a high heat radiation effect absorbs the heat generated in the power MOSFET 1, and discharges the absorbed heat to the surface of the electronic substrate opposite to the surface of the electronic substrate 8 on which the power MOSFET 1 is surface-mounted. Therefore, a higher heat radiation effect is obtained by forming through holes. These techniques are disclosed in Patent Document 1, for example.
Patent Document 1: JP-A-5-304223

However, if this technique is applied to a multilayer electronic substrate that is formed by laminating substrates on which patterns are formed, cracks are likely to be generated between the respective layers. For this reason, there is a concern that a conduction failure occurs on a current path on the electronic substrate 8 due to the generated cracks.

The details of the conduction failure will be described. FIG. 4 is a cross-sectional view of the electronic control device 1, which is shown in FIG. 3, taken along a line along an X-axis direction. An electronic substrate 8X is a multilayer substrate that is formed by laminating four substrates 15X on which patterns 11X are formed. The electronic substrate 8X includes through holes 12X through which the patterns 11X formed on the respective layers are electrically connected to each other. Each of the through holes 12X is a hole formed at the electronic substrate 8X. Edges of the holes are covered with metal having a conduction effect, and are electrically connected to the patterns 11X of the respective layers.

Further, the above-mentioned metal columns 13X for radiating heat are embedded in the electronic substrate 8X. Like the through holes 12X, edges 14X of holes (hereinafter, referred to as metal column holes) of the electronic substrate 8X, in which the metal columns 13X are embedded, are covered with metal having a conduction effect and are electrically connected to the patterns 11X of the respective layers.

If this heat radiating means is applied to the electronic control device including the multilayer electronic substrate, as shown in FIG. 4, a current path AX, which is formed of the flow of electricity input from the terminal plate 6X connected to the drain electrode, the flow of electricity output to the terminal 4X connected to the gate electrode, and the flow of electricity of the pattern 11X, goes through the metal columns 13X and the edges 14X of the metal column holes in the electronic substrate 8X. That is, a radiation path CX of heat, which is conducted to the metal columns 13X from the terminal plate 6X of the power MOSFET 1X and is discharged to the opposite side, partially overlaps with the current path AX.

Accordingly, a large amount of electricity (for example, current value: 45 A), which flows behind the terminal plate 6X of the power MOSFET 1 on the current path AX, is applied to the metal columns 13X that absorb the heat generated by the power MOSFET 1. Therefore, the metal columns 13X or the edges 14X of the metal column holes are likely to thermally expand. If the metal columns 13X or the edges 14X of the metal column holes thermally expand, cracks B are generated at the edges 14X of the metal column holes. For this reason, there is a concern that conduction failure occurs on the edges 14X of the metal column holes forming a part of the current path AX.

Moreover, since the edges 14X of the metal column holes and the metal columns 13X are also used as the current path, there also is a concern that the heat radiation effect of the metal columns 13X may deteriorate.

### SUMMARY

It is therefore an object of at least one embodiment of the present invention to provide an electronic control device including an electronic substrate that can prevent conduction failure, which is caused by the generation of cracks, from occurring on a current path while maintaining a heat radiating function of an electronic element.

In order to achieve at least one of the above-described objects, according to a first aspect of the embodiments of the present invention, there is provided an electronic control device that controls a control object, the electronic control device comprising: an electronic substrate on which an electronic component configured to control the control object is mounted; an electrical signal line formed on the electronic substrate, the electrical signal line that transmits an electrical signal; a metal that is press-fitted into the electronic substrate and passes through the electronic substrate to be exposed to both surfaces of the electronic substrate; and an electronic element having a contact surface portion which comes into contact with a surface of the electronic substrate when the electronic element is mounted on the electronic substrate, the electronic element connected to the electrical signal line, wherein the electronic element is mounted on the electronic substrate such that the contact surface portion comes into contact with the metal exposed to the both surfaces of the electronic substrate and the electrical signal line connected to the contact surface portion does not come into contact with the metal.

In the electronic control device, the electronic substrate may be a multilayer electronic substrate which is formed by laminating a plurality of substrates on which electrical signal lines are formed.

In the electronic control device, an inner surface of a through hole of the electronic substrate, which the metal passes through may be provided with a pattern which extends toward an inner layer of the multilayer electronic substrate, and the pattern may be not electrically connected to the electronic component other than the electronic element.

In the electronic control device, an electrical signal line which is electrically connected to the electronic component other than the electronic element may not come into contact with the metal.

In the electronic control device, the control object may be a motor, the electronic element may be a transistor sealed by a package which has the contact surface portion which comes into contact with the surface of the electronic substrate when the transistor is mounted on the electronic substrate, and the transistor may be configured to generates a current used to control the motor.

In the electronic control device, the electronic element may be a shunt resistor for current measurement.

Further, the electronic control device may be mounted on a vehicle.

According to a second aspect of the embodiments of the present invention, there is provided an electronic control device that controls a control object, the electronic control device comprising: an electronic substrate on which an electronic component configured to control the control object is mounted; an electrical signal line formed on the electronic substrate, the electrical signal line that transmits an electrical signal; a metal that is press-fitted into the electronic substrate and passes through the electronic substrate to be exposed to both surfaces of the electronic substrate; and an electronic element having a contact surface portion which comes into contact with a surface of the electronic substrate when the electronic element is mounted on the electronic substrate, the electronic element connected to the electrical signal line, wherein the electronic substrate is formed with the electrical signal line such that a current path including the electrical signal line connected to the contact surface portion of the electronic element does not overlap with a heat radiating path when the electronic element is mounted such that the contact surface portion comes into contact with the metal exposed to the both surface of the electronic substrate.

According to the above aspects of the embodiment of the present invention, an electronic element, which is sealed by a package and connects the electrical signal lines to the surface of the package that comes into contact with the surface of the electronic substrate when the electronic element is mounted on the electronic substrate, comes into contact with the metal of the electronic substrate that includes metal which passes through the surface of the package and is exposed. The electronic element is mounted on the electronic substrate, and the electrical signal lines of the electronic substrate, which are connected to the surface of the package of the electronic element, are formed so that the electrical signal lines do not come into contact with the metal. Accordingly, in the electronic control device including the electronic substrate, it may be possible to prevent conduction failure, which is caused by the generation of cracks, from occurring at a current path while maintaining the heat radiating function of an electronic element.

### BRIEF DESCRIPTION OF THE DRAWINGS

In the accompanying drawings:

FIG. 1 is a view illustrating an electronic element;

FIG. 2 is a view illustrating the electronic element;

FIG. 3 is a view illustrating an electronic control device;

FIG. 4 is a cross-sectional view illustrating the electronic control device;

FIG. 5 is a cross-sectional view illustrating the electronic control device;

FIG. 6 is a cross-sectional view illustrating the electronic control device;

FIG. 7 is a view illustrating the electronic element;

FIG. 8 is a view illustrating the electronic element;

### DETAILED DESCRIPTION OF THE EMBODIMENTS

The invention relates to a technique for an electronic control device that controls a control object, and is applied to an electronic control device in all technical fields. However, for convenience, a steering electronic control device, which controls an electric steering motor of a vehicle, will be described as an embodiment with reference to accompanying drawings.

### Typical Embodiment

### Electronic Element

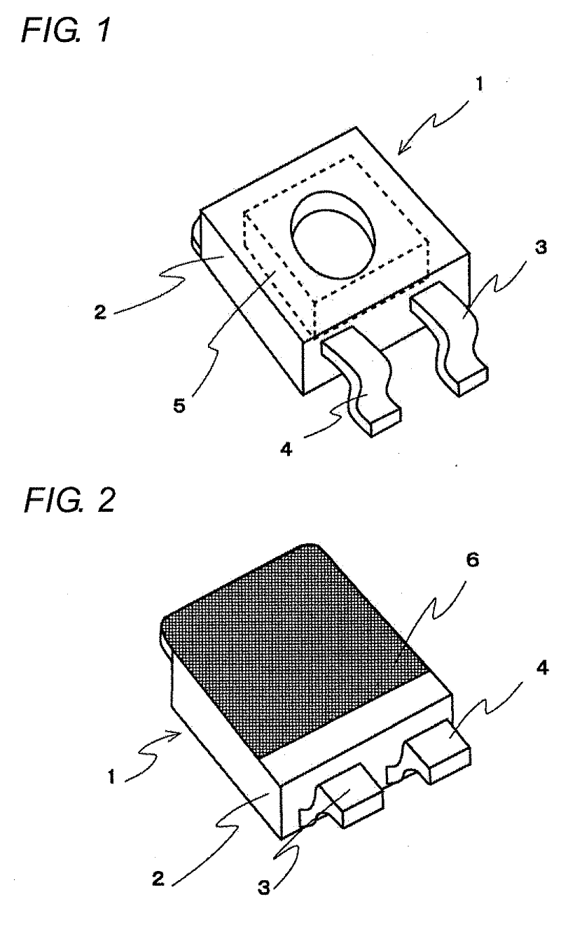

FIG. 1 shows a MOS field effect transistor, particularly, an electronic element called a power MOSFET. A transistor is used to control, for example, an electric steering motor that is a control object and is used to control a vehicle. Since the motor is a control object that requires large power, the motor needs to be controlled using, particularly, a power MOSFET.

In the power MOSFET, as shown in FIG. 1, a transistor chip 5, which is an electronic element, is sealed by a package 2. A source electrode and a gate electrode, among three electrodes of the transistor chip 5, are electrically connected to terminals 3 and 4, and these terminals are provided on the outside of the package 2. Further, as shown in FIG. 2 showing the back of the power MOSFET 1, a drain electrode, among the three electrodes of the transistor chip 5, is electrically connected to a terminal plate 6 and is exposed on the bottom of the package. The reason why only the drain electrode is disposed on the bottom of the package as described above is to achieve high integration and large power, and the power MOSFET 1 having this structure is suitable for achieving a reduction of the size and weight of a vehicle and the control of an electric steering motor that is mounted on a vehicle and requires a large output.

Furthermore, when the PWM control of a motor is performed by the realization of a switch function of the power MOSFET 1, a voltage is applied between the gate electrode and the drain electrode of the power MOSFET 1 and on-resistance is increased, so that heat is generated. For this reason, the terminal plate 6, which is exposed on the bottom of the package 2 of the power MOSFET 1 as shown in FIG. 2, also has a function of radiating heat generated in the package. The power MOSFET 1 is mounted on a surface of an electronic substrate that is provided in an electronic control device. (Electronic control device)

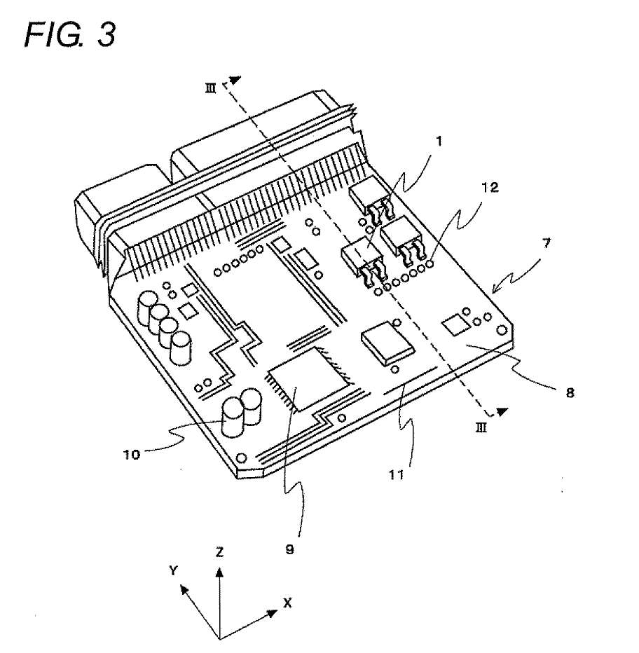

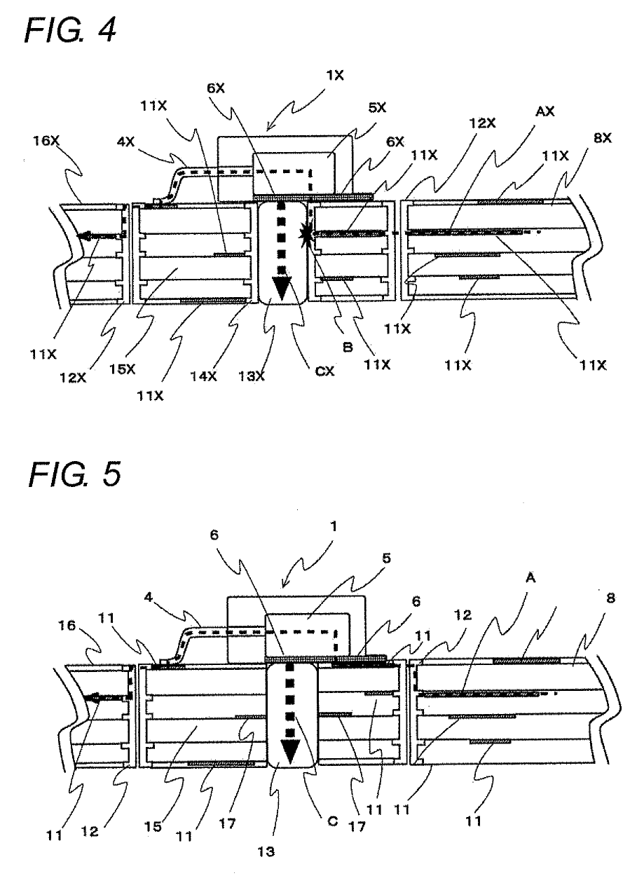

FIG. 3 shows an electronic control device 7. The electronic control device 7 has a function of controlling the electric steering motor, which is a control object, and includes an electronic substrate 8 on which electronic components are mounted. As described below, the electronic substrate 8 is formed of a multilayer electronic substrate that is formed by laminating a predetermined number of (for example, four) substrates on which electrical signal lines for transmitting electrical signals to the electronic components, that is, patterns are formed. Moreover, the electronic substrate 8 includes the above-mentioned power MOSFET 1; a memory, such as ROM or RAM, having a memory function; a microcomputer 9 including a CPU having a calculation function; a capacitor 10 having functions of accumulating and discharging charges; a pattern 11; through holes 12 that are electrically connected to patterns of electronic substrates which form other layers; and the like.

The electronic control device 7 is a steering electronic control device that controls an electric steering motor of a vehicle. The electronic control device controls the steering motor, which is a control object, on the basis of an input value obtained from a sensor, which senses physical phenomena, and a control program stored in the ROM or the like so that the CPU realizes a steering function in cooperation with other electronic components. (Electronic substrate)

FIG. 5 is a cross-sectional view of the electronic control device 1, which is shown in FIG. 3, taken along a line along an X-axis direction. The electronic substrate 8 is a multilayer electronic substrate that is formed by laminating a predetermined number of (for example, four) substrates 15 on which the patterns 11 are formed. The electronic substrate 8 includes through holes 12 through which the patterns 11 formed on the respective layers are electrically connected to each other. Each of the through holes 12 is a hole formed at the electronic substrate 8. Edges of the holes are covered with metal having a conduction effect, and are electrically connected to the patterns 11 of the respective layers. Here, both surfaces 16 of the electronic substrate 8 are coated with a resin or the like having an insulation effect.

Further, metal columns 13 for radiating heat are embedded in the electronic substrate 8. Metal column holes of the electronic substrate 8, in which the metal columns 13 are embedded, are not covered with the edges of the metal having the same conduction effect as the through holes 12 shown in FIG. 3. That is, the vicinity of the metal column hole is not electrically connected to the pattern 11 of each layer.

Furthermore, the electronic substrate 8 includes the pattern 11 so that the pattern 11 does not come into contact with the metal columns 13. When the power MOSFET 1 is mounted on the surface of the electronic substrate, the pattern 11 is electrically connected to the terminal plate 6 of the power MOSFET 1 that is a contact surface portion, which is a surface of the package of the power MOSFET 1, coming into contact with the surface of the electronic substrate 8. In other words, the electronic substrate 8 separates the pattern 11 from the metal columns 13 and makes the pattern 11 be not electrically connected to the metal columns 13. When the power MOSFET 1 is mounted on the surface of the electronic substrate, the pattern 11 is electrically connected to the terminal plate 6 of the power MOSFET 1 that is a contact surface portion, which is a surface of the package of the power MOSFET 1, coming into contact with the surface of the electronic substrate 8.

Accordingly, as shown in FIG. 5, a current path A, which is formed of the flow of electricity input from the terminal plate 6 connected to the drain electrode, the flow of electricity output to the terminal 4 connected to the gate electrode, and the flow of electricity of the pattern 11, does not go through or does not come into contact with the metal columns 13 in the power MOSFET 1.

Therefore, a radiation path C of heat, which is conducted to the metal columns 13 from the terminal plate 6 of the power MOSFET 1 and is discharged to the opposite side, does not overlap with the current path A, so that electricity does not flow at the edges of the metal column hole of the electronic substrate 8. As a result, the metal columns 13 do not thermally expand and cracks B are also not generated at the edges 14 of the metal column hole. That is to say, it may be possible to prevent the heat radiation effect of the metal columns 13 from deteriorating as well as to prevent conduction failure, which is caused by the generation of the cracks B, from occurring at the current path A.

Here, the patterns 11 are inner layers of the electronic substrate 8, clamp the side surface of the metal column 13, and are not electrically connected to the patterns 11 or the electronic components. Accordingly, the electronic substrate 8 may fix the metal column 13.

<Modifications>

The embodiment of the invention has been described above. However, the invention is not limited to the above-mentioned embodiment, and may have various modifications. In regard to the other embodiments, the differences with above-mentioned embodiment will be mainly described below.

<First Modification>

An electric steering motor has been described as a control object in the above-mentioned embodiment. However, a throttle motor, a transmission gear solenoid, a cooling fan motor, a power window motor, an airbag squib, a seat motor, an air conditioner motor, a wiper motor, or the like may be a control object.

Further, in the above-mentioned embodiment, a steering electronic control device for controlling an electric steering motor has been described as an electronic control device. However, an engine electronic control device for controlling a throttle motor, a transmission electronic control device for controlling a transmission gear solenoid, a cooling fan electronic control device for electronically controlling a cooling fan motor, a power window electronic control device for controlling a power window motor, an airbag electronic control device for controlling an airbag squib, a seat electronic control device for controlling a seat motor, an air conditioner electronic control device for controlling an air conditioner motor, a wiper electronic control device for controlling a wiper motor, or the like may be an electronic control device.

<Second Modification>

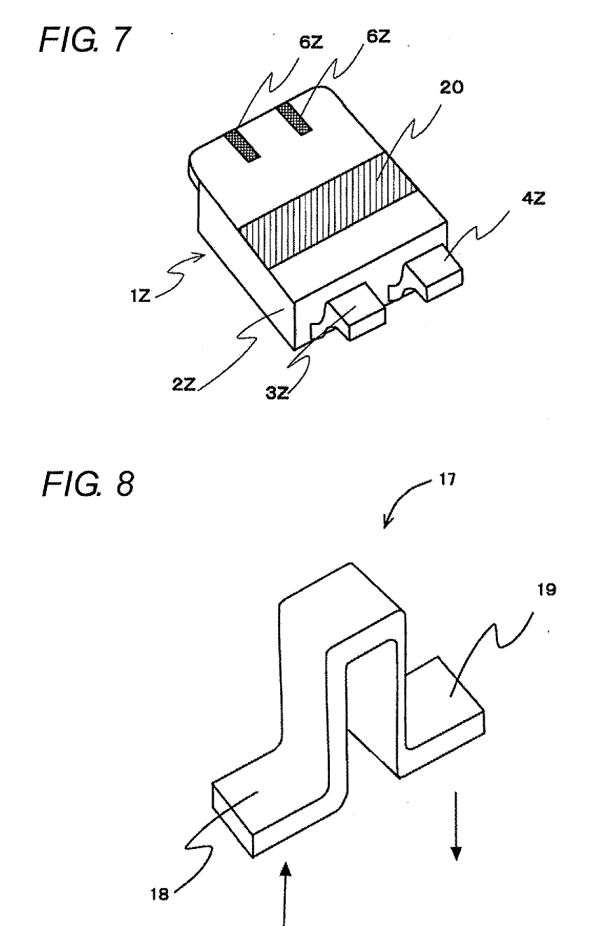

In the above-mentioned embodiment, the drain electrode, among the three electrodes of the transistor chip 5, of the power MOSFET 1, which is an electronic element, has been electrically connected to the terminal plate 6 and is exposed on the bottom of the package as shown in FIG. 2, and the terminal plate 6 which is exposed on the bottom has also had a function of radiating heat generated in the package. However, in a power MOSFET 1, the drain electrode, among the three electrodes of the transistor chip, may be electrically connected to two terminal plates 6Z and be exposed on the bottom of a package 2Z, and a heat radiating plate 20 for radiating heat generated in the package 2Z separately may be exposed on the bottom of the package 2Z as shown in FIG. 7.

Even in a power MOSFET 1Z that is this electronic element, it may be possible to obtain the same advantages as the invention.

<Third Modification>

In the above-mentioned embodiment, the power MOSFET 1 shown in FIGS. 1 and 2 has been described as an electronic element. However, any electronic element may be applied as long as an electronic element is mounted on the surface of the electronic substrate and generates heat during the realization of a function like the power MOSFET 1, a contact surface portion of the electronic element, which comes into contact with the electronic substrate when the electronic element is mounted on the surface of the electronic substrate, forms a part of a current path, and the electronic element can discharge the generated heat from the contact surface portion.

For example, an electronic element such as a shunt resistor 17 shown in FIG. 8 can be considered. The shunt resistor is a resistance unit that is used to detect current of a circuit.

The shunt resistor 17, which is used for this purpose, also generates heat while realizing a function of detecting current. Terminals 18 and 19, that is, contact surface portions of the shunt resistor, which come into contact with the electronic substrate when the shunt resistor is mounted on the surface of the electronic substrate, form a part of a current path and can discharge the generated heat from the terminals 18 and 19.

Accordingly, even in the shunt resistor 17 that is this electronic element, it may be possible to obtain the same advantages as the invention.

<Fourth Modification>

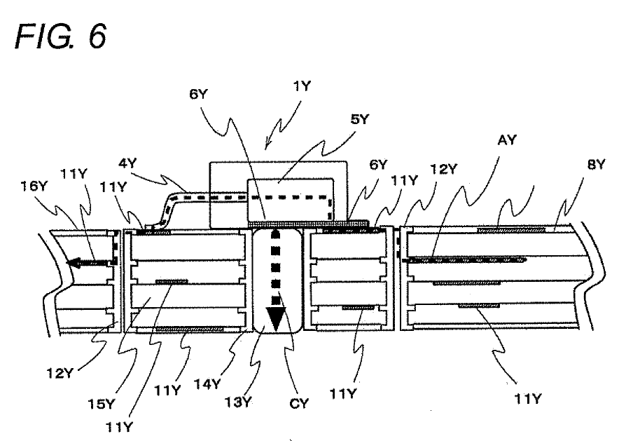

A current path different from the current path of the electronic substrate of the above-mentioned embodiment will be described. FIG. 6 is a cross-sectional view of the electronic control device 1, which is shown in FIG. 3, taken along the line III-III along the X-axis direction. An electronic substrate 8Y is a multilayer electronic substrate that is formed by laminating a predetermined number of (for example, four) substrates 15Y on which patterns 11Y are formed. The electronic substrate 8Y includes through holes 12Y through which the patterns 11Y formed on the respective layers are electrically connected to each other. Each of the through holes 12Y is a hole formed at the electronic substrate 8Y. Edges of the holes are covered with metal having a conduction effect, and are electrically connected to the patterns 11Y of the respective layers. Here, both surfaces 16Y of the electronic substrate 8Y are coated with a resin or the like having an insulation effect.

Further, the above-mentioned metal columns 13Y for radiating heat are embedded in the electronic substrate 8Y. Edges 14Y of metal column holes of the electronic substrate 8Y, in which metal is embedded, are covered with metal having a conduction effect like the through holes 12Y, but are not electrically connected to the patterns 11Y of the respective layers.

Furthermore, the electronic substrate 8Y includes the pattern 11Y so that the pattern 11Y is led in a direction away from the metal columns 13Y and is not electrically connected to the metal columns 13Y and the edges 14Y of metal column holes. When a power MOSFET 1Y is mounted on the surface of the electronic substrate, the pattern 11Y is electrically connected to a terminal plate 6Y of the power MOSFET 1Y that is a contact surface portion, which is a surface of the package of the power MOSFET 1Y, coming into contact with the surface of the electronic substrate 8Y.

That is to say, as shown in FIG. 6, a current path AY, which is formed of the flow of electricity input from the terminal plate 6Y connected to a drain electrode, the flow of electricity output to a terminal 4Y connected to a gate electrode, and electricity flowing at the pattern 11Y, does not go through or does not come into contact with the metal columns 13Y or the edges 14Y of metal column holes in the power MOSFET 1Y.

Therefore, a radiation path CY of heat, which is conducted to the metal columns 13Y from the terminal plate 6Y of the power MOSFET 1Y and is discharged to the opposite side, does not overlap with the current path AY, so that electricity does not flow at the edges of the metal column holes of the electronic substrate 8Y. As a result, the metal columns 13Y do not thermally expand and cracks B are also not generated at the edges 14Y of the metal column hole. That is, it may be possible to prevent a heat radiation effect of the metal columns 13Y from deteriorating as well as to prevent conduction failure, which is caused by the generation of the cracks BY, from occurring at the current path AY.

Here, the edges 14Y of the metal column holes are formed at the electronic substrate 8Y so as to clamp the side surface of the metal column 13Y and so as not to be electrically connected to the other patterns 11Y or electronic components. Accordingly, the electronic substrate 8Y may fix the metal column 13Y and improve a heat radiation effect.

<Fifth Modification>

A current path different from the current path of the electronic substrate of the above-mentioned embodiment will be described. In the above-mentioned embodiment, the electronic substrate 8 includes the pattern 11 so that the pattern 11 is led in the direction away from the metal columns 13 and comes into contact with the metal columns 13 and the metal columns 13 are not grounded. When a power MOSFET 1 is mounted on the surface of the electronic substrate, the pattern 11 is electrically connected to a terminal plate 6 of the power MOSFET 1 that is a contact surface portion, which is a surface of the package of the power MOSFET 1, coming into contact with the surface of the electronic substrate 8.

Accordingly, since the metal columns 13 are not grounded even though the pattern 11 comes into contact with the metal columns 13, current does not flow at the edges 14 of the metal column holes or the metal columns 13. Therefore, a radiation path C of heat, which is conducted to the metal columns 13 from the terminal plate 6 of the power MOSFET 1 and is discharged to the opposite side, does not overlap with the current path A, so that electricity does not flow at the edges 14 of the metal column holes of the electronic substrate 8, the metal columns 13Y do not thermally expand, and cracks B are also not generated at the edges 14 of the metal column hole. That is, it may be possible to prevent a heat radiation effect of the metal columns 13 from deteriorating as well as preventing conduction failure, which is caused by the generation of the cracks B, from occurring at the current path A.

What is claimed is:

1. An electronic control device that controls a control object, the electronic control device comprising:
an electronic substrate on which an electronic component configured to control the control object is mounted;
an electrical signal line formed on the electronic substrate, the electrical signal line that transmits an electrical signal;
a metal that is press-fitted into the electronic substrate and passes through the electronic substrate to be exposed to both surfaces of the electronic substrate; and
an electronic element having a contact surface portion which comes into contact with a surface of the electronic substrate when the electronic element is mounted on the electronic substrate, the electronic element connected to the electrical signal line,
wherein the electronic element is mounted on the electronic substrate such that the contact surface portion comes into contact with the metal exposed to the both surfaces of the electronic substrate and the electrical signal line connected to the contact surface portion does not come into contact with the metal.

2. The electronic control device as set forth in claim 1, wherein the electronic substrate is a multilayer electronic substrate which is formed by laminating a plurality of substrates on which electrical signal lines are formed.

3. The electronic control device as set forth in claim 2,
wherein an inner surface of a through hole of the electronic substrate, which the metal passes through is provided with a pattern which extends toward an inner layer of the multilayer electronic substrate, and
wherein the pattern is not electrically connected to the electronic component other than the electronic element.

4. The electronic control device as set forth in claim 1, wherein an electrical signal line which is electrically connected to the electronic component other than the electronic element does not come into contact with the metal.

5. The electronic control device as set forth in claim 1,
wherein the control object is a motor,
wherein the electronic element is a transistor sealed by a package which has the contact surface portion which comes into contact with the surface of the electronic substrate when the transistor is mounted on the electronic substrate, and
wherein the transistor is configured to generates a current used to control the motor.

6. The electronic control device as set forth in claim 1, wherein the electronic element is a shunt resistor for current measurement.

7. The electronic control device as set forth in claim 1, wherein the electronic control device is mounted on a vehicle.

8. An electronic control device that controls a control object, the electronic control device comprising:
an electronic substrate on which an electronic component configured to control the control object is mounted;
an electrical signal line formed on the electronic substrate, the electrical signal line that transmits an electrical signal;
a metal that is press-fitted into the electronic substrate and passes through the electronic substrate to be exposed to both surfaces of the electronic substrate; and
an electronic element having a contact surface portion which comes into contact with a surface of the electronic substrate when the electronic element is mounted on the electronic substrate, the electronic element connected to the electrical signal line,
wherein the electronic substrate is formed with the electrical signal line such that a current path including the electrical signal line connected to the contact surface portion of the electronic element does not overlap with a heat radiating path when the electronic element is mounted such that the contact surface portion comes into contact with the metal exposed to the both surface of the electronic substrate.
